(19) United States
(12) Patent Application Publication
(10) Pub. No.: US 2026/0085220 A1
(43) Pub. Date: Mar. 26, 2026

(54) POLISHING COMPOSITION AND POLISHING METHOD USING THE SAME

(71) Applicant: FUJIMI INCORPORATED, Aichi (JP)

(72) Inventor: Sheng-Hsuan Wei, Aichi (JP)

(21) Appl. No.: 19/327,139

(22) Filed: Sep. 12, 2025

(30) Foreign Application Priority Data
Sep. 25, 2024 (JP) 2024-166347

(51) Int. Cl. C09K 3/14; H01L 21/321

(52) U.S. Cl. CPC C09K 3/1463; C09K 3/1436; H10P 52/403

(57) ABSTRACT

The present disclosure provides a polishing composition containing: abrasive grains having surfaces modified with a silane coupling agent and having a positive surface potential, and having an average secondary particle size of 45 nm or more and 100 nm or less, and a silanol group density of more than 0.0/nm² and 3.0/nm² or less; a surfactant which is an alkyl phosphate having 6 to 18 carbon atoms; and an aqueous dispersing medium.

### CROSS-REFERENCE TO RELATED APPLICATION

The present application is based on the Japanese patent application No. 2024-166347, which is a foreign language written application filed on Sep. 25, 2024, and the disclosed content thereof is incorporated herein as a whole by reference.

### TECHNICAL FIELD

The present disclosure provides a polishing composition and a polishing method using the same.

### BACKGROUND ART

In recent years, with development of the semiconductor technology, further downsizing in designing semiconductors has been advanced, and the number of layers laminated has been increasing. In order to flatten the circuit structure of each layer, various polishing processes such as a chemical mechanical polishing (CMP) process are generally used to increase the flatness of the surface of a semiconductor substrate or the surface of a wafer. The chemical mechanical polishing technology is generally a technology in which an object to be polished is polished by using a chemical mechanical polishing composition containing abrasive grains, a surfactant, and the like.

The object to be polished may be, for example, an object to be polished containing a material containing a nitride such as TiN; or an object to be polished containing a material containing single crystal silicon, polycrystalline silicon, silica, a silicon nitride, or the like. Therefore, the polishing percentage of each material needs to be controlled, since the material of the object to be polished or the function desired to be obtained is different in each process.

For example, Patent Literature 1 discloses that an inherent performance of polishing an object to be polished containing a silicon material having a silicon-silicon bond can be maintained. Patent Literature 2 discloses a polishing composition that can enhance the polishing removal rate of a metal (in particular, tungsten) excellent in the embedding property and can maintain the stability as a composition. Patent Literature 3 discloses a polishing composition that can polish a material containing a silicon atom or a material such as TiN at a high speed. Based on Patent Literatures 1 to 3, it is found that the composition of the polishing composition is generally different depending on the purpose thereof and the object to be polished.

### CITATION LIST

### Patent Literature

Patent Literature 1: Japanese Patent Laid-Open No. 2020-158752
Patent Literature 2: Japanese Patent Laid-Open No. 2021-161385
Patent Literature 3: Japanese Patent Laid-Open No. 2022-108413

### SUMMARY OF DISCLOSURE

However, with regard to the chemical mechanical polishing composition disclosed in each of Patent Literatures 1 to 3, the selectivity between silicon and other materials (such as a nitride material) or the like is not studied.

Therefore, an object of the present disclosure is to provide a polishing composition that can achieve increased polishing removal rate of a silicon-containing material and has a high selectivity of the silicon-containing material with respect to other materials (such as a nitride material), and that can maintain the stability of the composition.

In order to achieve the object, an aspect of the present disclosure provides a polishing composition containing: abrasive grains having surfaces modified with a silane coupling agent and having a positive surface potential, and having an average secondary particle size of 45 nm or more and 100 nm or less, and a silanol group density of more than 0.0/nm² and 3.0/nm² or less; a surfactant which is an alkyl phosphate having 6 to 18 carbon atoms; and an aqueous dispersing medium.

Another aspect of the present disclosure further provides a polishing method that can achieve the above object, and the polishing method is a polishing method including the steps of: providing a polishing apparatus including a polishing pad and a polishing head; providing a substrate between the polishing pad and the polishing head; and introducing a polishing composition between the substrate and the polishing pad and then polishing the substrate, wherein the polishing composition contains: abrasive grains having surfaces modified with a silane coupling agent and having a positive surface potential, and having an average secondary particle size of 45 nm or more and 100 nm or less, and a silanol group density of more than 0.0/nm² and 3.0/nm² or less; a surfactant which is an alkyl phosphate having 6 to 18 carbon atoms; and an aqueous dispersing medium.

The polishing composition of the present disclosure has a high removal percentage of a silicon-containing material, and, at the same time, can suppress the polishing removal rate of other materials (in other words, the selectivity of a silicon material with respect to a material other than the silicon material (such as a nitride film) is high), and excellent stability can be maintained even under high temperature environments for a long period of time. With the polishing method of the present disclosure, by using the polishing composition, a surface of a semiconductor substrate or a surface of a wafer having a desired effect can be obtained, and the production cost of the semiconductor substrate or the wafer can also be reduced.

### DESCRIPTION OF EMBODIMENTS

Embodiments of the present disclosure will hereinafter be described, but the present disclosure is not limited to the embodiments described below, and various modifications could be made within the scope of the claims. The embodiments described in the present specification could be arbitrarily combined for another embodiment.

The terms “contain” “comprise” and “include” in the present specification indicate presence of a member, an integer, a step, an operation, an element, a composition, and/or a group thereof having the described feature, but it will be understood that presence or addition of one or a plurality of members, integers, steps, operations, elements, compositions, and/or a group thereof having other features is not precluded. In the present specification, if a term is described in a singular form, it is intended to include a plural form thereof unless otherwise specified in the preceding or following sentence.

The expression “a to b” used for describing a specific numerical range in the present specification is defined as “≥a and ≤b” (a or more and b or less).

### <Polishing Composition>

The polishing composition of the present embodiment contains: abrasive grains having surfaces modified with a silane coupling agent and having a positive surface potential, and having an average secondary particle size of 45 nm or more and 100 nm or less, and a silanol group density of more than 0.0/nm² and 3.0/nm² or less; a surfactant which is an alkyl phosphate having 6 to 18 carbon atoms; and an aqueous dispersing medium.

In one or more embodiments, the polishing composition is suitable for, for example, use of processing a specific object to be polished in a process of a semiconductor apparatus. In an embodiment, examples of the object to be polished include a surface containing single crystal silicon, polycrystalline silicon, silicon oxide, silicon nitride, other silicon compounds, or metal nitride. Of these, the polishing composition is suitable for use of polishing a semiconductor substrate containing silicon oxide. The polishing composition is particularly suitable for use of polishing a semiconductor substrate further containing a metal nitride, and examples of the metal nitride material may include titanium nitride (TiN), tantalum nitride, or a combination thereof, although the metal nitride material is not limited. In an embodiment, examples of the polishing composition include a polishing composition such that the silicon oxide is polished at a high polishing removal rate with respect to the metal nitride. Therefore, according to an embodiment, the object to be polished contains silicon oxide and metal nitride. In an embodiment, the processing method described above is not particularly limited, and examples thereof include polishing processing, selective polishing processing, and cleaning processing. The polishing composition of the present embodiment is preferably used for polishing processing and selective polishing processing.

The polishing composition of the present embodiment will hereinafter be described in detail.

### <Abrasive Grains>

Examples of the abrasive grains in the polishing composition are not limited, but may include alumina, silica, zirconia, diamond, or silicon carbide. The abrasive grains preferably contain silica having a silanol group density of more than 0.0/nm² and 3.0/nm² or less. As the abrasive grains, one type thereof may be used alone, or two or more types thereof may be used in combination. As the abrasive grains, a commercially available product may be used, or a synthesized product may be used.

The abrasive grains have a positive surface potential on the surface thereof, and are sometimes referred to as cation-modified abrasive grains below. The abrasive grains are preferably colloidal silica having a cationic group (cation-modified colloidal silica), and particularly preferably colloidal silica having an amino group (amino group-modified colloidal silica). The abrasive grains having a cationic group can further increase the polishing removal rate of the object to be polished containing a silicon-containing material (such as a silicon oxide film). In general, the surface of a metal nitride is generally positively charged under acidic environments, and, therefore, repulsive force is generated between the abrasive grains having a cationic group having a positive surface potential on the surface thereof and the surface of the metal nitride, whereby collision between the abrasive grains and the surface of the metal nitride is avoided, whereby occurrence of scratch can be suppressed. However, this mechanism is based on a presumption, and, therefore, the present disclosure is not affected by the presumption.

In one or more embodiments, the abrasive grains are surface-modified by chemical treatment with a silane coupling agent having an amino group. In the present specification, the surface modification by chemical treatment is also referred to as chemical surface modification. By the chemical surface treatment, the amino group is immobilized on the surface of the abrasive grains, and the abrasive grains are cationized. This immobilization is chemical bonding, not physical adsorption. Examples of a method for producing the abrasive grains having an amino group include a method in which a silane coupling agent having an amino group such as aminoethyl trimethoxysilane is immobilized on, for example, the surface of a silica particle described in Japanese Patent Laid-Open No. 2005-162533.

In the present specification, the silane coupling agent having an amino group is referred to as “aminosilane coupling agent”.

Examples of the aminosilane coupling agent include 3-aminopropyltrimethoxysilane, (3-aminopropyl)triethoxysilane (APTES), 4-amino3,3-dimethylbutyltriethoxysilane, N-methylaminopropyltrimethoxysilane, (N,N-dimethyl-3-aminopropyl)trimethoxysilane, 2-(4-pyridylethyl)triethoxysilane, N-(2-aminoethyl)-3-aminopropyltrimethoxysilane, N-(2-aminoethyl)-3-aminopropylsilanetriol, 3-trimethoxysilylpropyl diethyldiethylenetriamine, N,N′-BIS [(3-trimethoxysilyl)propyl]ethylenediamine], [3-(1-piperazinyl)propyl]methyldimethoxysilane, N-2-(aminoethyl)-3-aminopropylmethyldimethoxysilane, 3-triethoxysilyl-N-(1,3-dimethyl-butylidene)propylamine, N-phenyl-3-aminopropyltrimethoxysilane, N-(vinylbenzyl)-2-aminoethyl-3-aminopropyltrimethoxysilane hydrochloride, N-(1,3-dimethylbutylidene)-3-(triethoxysilyl)-1-propanamine, and bis[3-(trimethoxysilyl)propyl]amine.

As the aminosilane coupling agent, specifically, the aminotrialkoxysilane having a structure represented by the following formula (1) can be used, for example. In the formula (1), X is an alkyl group having 1 or more and 10 or less carbon atoms (C) (hereinafter described as C₁ to C₁₀), an aminoalkyl (C₁ to C₁₀) containing 1 or more nitrogen, or a single bond. R₁, R₂, and R₃ are each independently an alkyl group (C₁ to C₃), hydrogen (H), or a salt thereof. The salt may be, for example, hydrochloride.

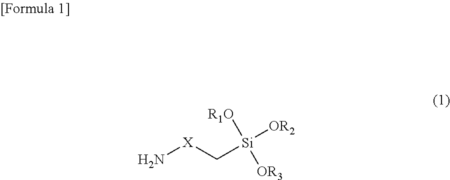

Examples of the aminotrialkoxysilane include 3-aminopropyltrimethoxysilane, 3-aminopropyltriethoxysilane (APTES), 4-amino3,3-dimethylbutyltriethoxysilane, N-methylaminopropyltrimethoxysilane, (N,N-dimethyl-3-aminopropyl)trimethoxysilane, N-(2-aminoethyl)-3-aminopropyltrimethoxysilane, N-(2-aminoethyl)-3-aminopropylsilanetriol, and 3-trimethoxysilylpropyl diethyldiethylenetriamine. Of the aminosilane coupling agents described above, 3-aminopropyltriethoxysilane (APTES) has a structure represented by the formula (2). Where 3-aminopropyltriethoxysilane is used as the aminosilane coupling agent, an aminopropyl group is immobilized on the surface of the abrasive grains, whereby the abrasive grains are cationized.

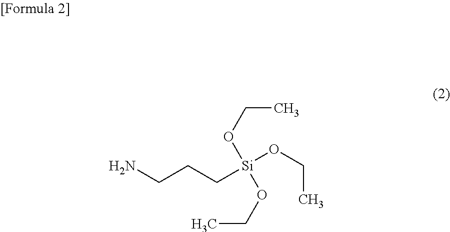

The zeta (ζ) potential of the cationized abrasive grains surface-modified by the chemical treatment with the aminosilane coupling agent is preferably 10 mV or more, more preferably 20 mV or more, and further preferably 30 mV or more under acidic conditions. From the viewpoint of stably obtaining a positive zeta potential, as the aminosilane coupling agent, it is preferred to use the aminotrialkoxysilane, and, among the aminotrialkoxysilane, it is preferred to use APTES.

The aminosilane coupling agent generates a chemical bond between the aminosilane coupling agent and colloidal silica, which is for example, a Si—O—Si bond, by hydrolysis reaction and dehydration condensation reaction in the chemical treatment. The zeta potential of cationized colloidal silica surface-modified by the chemical treatment with the aminosilane coupling agent in this manner has a larger positive value than unmodified colloidal silica under acidic conditions. Thus, the effect of the present disclosure can be easily obtained. Ordinary colloidal silica is such that the value of the zeta potential is close to 0 under acidic conditions, and, therefore, the particles of colloidal silica do not electrically repulse each other and are likely to aggregate under acidic conditions. In contrast, the particles of cationized colloidal silica strongly repulse each other to satisfactorily disperse, whereby the particles are less likely to aggregate even under acidic conditions. As a result, the storage stability of the polishing composition is enhanced. However, this mechanism is based on a presumption, and, therefore, the present disclosure is not affected by the presumption.

The aspect ratio of the surface-modified abrasive grains is preferably 1.0 or more, more preferably 1.02 or more, further preferably 1.05 or more, and even more preferably 1.10 or more from the viewpoint of the polishing removal rate. The aspect ratio of the surface-modified cationized colloidal silica is preferably less than 1.4, more preferably 1.35 or less, further preferably 1.25 or less, and most preferably 1.20 or less. Thus, the surface roughness of the object to be polished due to the shape of the abrasive grains can be satisfactory. Also, occurrence of defects due to the shape of the abrasive grains can be suppressed. The aspect ratio is an average value of values obtained by dividing the length of the long side of the smallest rectangle circumscribing each particle of the colloidal silica by the length of the short side of the same rectangle, and can be determined by using a common image analysis software from the image of the abrasive grains obtained with a scanning electron microscope.

The average primary particle size of the abrasive grains according to the present embodiment is preferably 100 nm or less, more preferably 70 nm or less, further preferably 50 nm or less, still more preferably 40 nm or less, and even more preferably 35 nm or less. The average primary particle size of the abrasive grains according to the present embodiment is preferably 5 nm or more, more preferably 10 nm or more, further preferably 20 nm or more, still more preferably 25 nm or more, even more preferably 30 nm or more, particularly preferably 35 nm or more, and most preferably more than 35 nm. If the average primary particle size is within such a range, the polishing removal rate of the object to be polished by the polishing composition is enhanced. Also, occurrence of dishing on the surface of the object to be polished after being polished by using the polishing composition can be further suppressed. The average primary particle size of the colloidal silica is calculated based on, for example, the specific surface area of the colloidal silica measured by the BET method.

The average secondary particle size of the abrasive grains according to the present embodiment is preferably 300 nm or less, more preferably 200 nm or less, further preferably 150 nm or less, still more preferably 100 nm or less, even more preferably 90 nm or less, particularly preferably 80 nm or less, and especially preferably 75 nm or less. The average secondary particle size of the abrasive grains according to the present embodiment is preferably 50 nm or more, more preferably 55 nm or more, further preferably 60 nm or more, and still more preferably 63 nm or more. According to an embodiment, the average secondary particle size of the abrasive grains is 50 nm or more and 150 nm or less, 50 nm or more and 120 nm or less, 50 nm or more and 100 nm or less, or 50 nm or more and 80 nm or less. If the average secondary particle size is within such a range, the polishing removal rate of the object to be polished by the polishing composition is enhanced. Also, occurrence of surface defects on the surface of the object to be polished after being polished by using the polishing composition can be further suppressed.

The secondary particle refers to a particle formed when the colloidal silica having an organic acid immobilized on the surface thereof (primary particle) is aggregated in the polishing composition. The average secondary particle size of the secondary particle can be measured by, for example, a dynamic light scattering method.

In one or more embodiments, the abrasive grains used in the embodiment have a silanol group on the surface thereof. The term “silanol group” in the present specification refers to a group formed when a hydroxy group is directly bonded to the silicon atom on the surface of the silica particle, and the configuration or the coordination geometry is not particularly limited. Also, the generation condition or the like of the silanol group is not particularly limited. The term “silanol group density” in the present specification refers to the number of the silanol groups per unit area on the surface of the silica particle, and is an index indicating the electric property or the chemical property of the surface of the silica particle. In an embodiment in which silica may be contained in the abrasive grains, the silanol group density of the abrasive grains is preferably 0.0 to 5.0/nm², more preferably 0.5 to 3.0/nm², further preferably 1.0 to 3.0 nm², still more preferably 1.5 to 3.0/nm², and most preferably 1.5 to 2.5/nm². According to an embodiment, the silanol group density of the abrasive grains is 0.5 to 3.0/nm², 0.8 to 3.0/nm², 1.2 to 3.0/nm², 0.5 to 2.0/nm², 0.8 to 2.0/nm², or 1.2 to 2.0/nm². If the abrasive grains in the polishing composition have the silanol group density within the above range, the polishing composition can achieve a satisfactory polishing property and the stability is better.

The silanol group density of the abrasive grains in the polishing composition is calculated and determined based on the specific surface area measured by the BET method and the amount of the silanol groups measured by titration. For example, the average silanol group density (unit: number/nm²) on the surface of the silica (polishing abrasive grains) can be calculated by the Sears titration method using neutralization titration described in “Analytical Chemistry, vol. 28, No. 12, 1956, 1982-1983” by G. W. Sears.

The shape of the abrasive grains used in the present embodiment is not particularly limited, and the shape may be spherical or non-spherical. Specific examples of the non-spherical shape include various shapes such as a polygonal shape such as a triangular prism and a quadrangular prism, a cylindrical shape, a barrel-like shape in which the central part of a column is bulged compared with the end part, a ring-like shape (doughnut-like shape) in which the central part of a disk is penetrated, a plate-like shape, a shape known as a cocoon-like shape having a constriction in the central part, a shape known as an aggregated-type spherical shape in which a plurality of particles are aggregated into a single body, a shape known as a kompeito-like shape having a plurality of protrusions on the surface, and a rugby ball-like shape, which are not particularly limited.

The content (concentration) of the abrasive grains used in the present embodiment is not particularly limited. The content of the abrasive grains in the polishing composition is preferably 0.01% by weight or more, more preferably 0.1% by weight or more, still more preferably 1% by weight or more, and most preferably 1.5% by weight or more, based on 100% by weight of the total weight of the polishing composition. As the content of the abrasive grains in the polishing composition increases, the removal percentage of the object to be polished by the polishing composition increases. The content of the abrasive grains in the polishing composition is preferably 20% by weight or less, more preferably 15% by weight or less, and most preferably 10% by weight or less. As the content of the abrasive grains in the polishing composition decreases, the proportion of scratch defects on the surface of the object to be polished decreases. In other words, the content of the abrasive grains in the polishing composition is preferably within the range of 0.01 to 20% by weight, more preferably within the range of 0.1 to 15% by weight, and most preferably within the range of 1 to 10 wt %. In an embodiment, the content of the abrasive grains in the polishing composition is preferably within the range of 0.01 to 20% by weight, more preferably within the range of 0.1 to 15% by weight, further preferably within the range of 1 to 10% by weight, and most preferably within the range of 1.5 to 5% by weight. If the content of the abrasive grains in the polishing composition is within the above range, the polishing composition can increase the removal percentage of the object to be polished, while maintaining the proportion of scratch defects of the object to be polished low, whereby the polishing composition has a good polishing property.

### <Surfactant>

The surfactant used in the polishing composition in one or more embodiments may be an alkyl phosphate (ester) having 6 to 18 carbon atoms (C₆ to C₁₈ alkyl phosphate). When the polishing composition contains an alkyl phosphate having 6 to 18 carbon atoms (C₆ to C₁₈ alkyl phosphate) as a surfactant, the selectivity of the silicon-containing material with respect to other materials (such as a nitride material) can be enhanced, while enhancing the polishing removal rate of the silicon-containing material. The reason thereof is presumed that the alkyl phosphate having 6 to 18 carbon atoms (C₆ to C₁₈ alkyl phosphate) has a low property of being adsorbed on the silicon-containing material, and is likely to be adsorbed on other materials (such as a nitride material). Thus, it is considered that the silicon-containing material can be selectively polished compared with other materials (such as a nitride material). Where the number of carbon atoms of the alkyl phosphate is less than 6, the property of being adsorbed on other materials (such as a nitride material) decreases, whereby the selectivity of the silicon-containing material with respect to other materials (such as a nitride material) decreases. Where the number of carbon atoms of the alkyl phosphate is more than 18, the stability of the polishing composition is deteriorated, whereby aggregation or deposition occurs. The number of carbon atoms of the alkyl phosphate is preferably 6 or more, more preferably 8 or more, and further preferably 10 or more. The number of carbon atoms of the alkyl phosphate is preferably 17 or less, more preferably 16 or less, further preferably 15 or less, and still more preferably 14 or less. According to an embodiment, the number of carbon atoms of the alkyl phosphate is preferably 6 or more and 16 or less, 8 or more and 16 or less, 10 or more and 16 or less, 10 or more and 14 or less, or 10 or more and 12 or less. In an embodiment, it is preferred that the alkyl group having 6 to 18 carbon atoms (C₆ to C₁₈ alkyl group) is directly bonded to the phosphate, and, in other words, it is preferred that the alkyl group and the phosphate do not have other bonds such as an alkenyl group, an alkyne group, and other hetero atoms therebetween. In another embodiment, the alkyl phosphate may be an alkyl phosphate formed when a phosphate and one or more alkyl groups are bonded to each other, and a monoalkyl phosphate formed when a phosphate and one alkyl group are bonded to each other is preferred. When the object to be polished is polished with the polishing composition containing the alkyl phosphate, scratch that may occur due to the abrasive grains can be suppressed, whereby the surface of the substrate can be protected. However, if the chain of the alkyl group is excessively long, a problem arises that the solubility is insufficient, thereby deteriorating the stability of the polishing composition, whereby the polishing composition cannot be stored for a long period of time.

The phrase “alkyl group having 6 to 18 carbon atoms (C₆ to C₁₈ alkyl group)” in the present specification refers to a monovalent alkyl group resulting from removing one hydrogen atom from a saturated hydrocarbon molecule containing 6 to 18 carbon atoms. The C₆ to C₁₈ alkyl group may be a linear alkyl group, a branched alkyl group, or a cyclic alkyl group. Examples of the linear alkyl group may include a n-hexyl group, a n-heptyl group, a n-octyl group, a n-nonyl group, a n-decyl group, a lauryl group (dodecane group), a tridecane group, a myristyl group (tetradecane), a pentadecane group, a palmityl group (hexadecane group), a heptadecane group, and a stearyl group (octadecane group), although the linear alkyl group is not limited. Examples of the branched alkyl group may include an isohexyl group, an isoheptyl group, an isooctyl group, an isononyl group, an isodecyl group, an isoundecane group, an isododecane group, an isotridecane group, an isotetradecane group, an isopentadecane group, an isohexadecane group, and isoheptadecane group, although the branched alkyl group is not limited. In an embodiment, as an alkyl phosphate having 6 to 18 carbon atoms (C₆ to C₁₈ alkyl phosphate), it is more preferred to use a phosphate having a linear or branched alkyl group, and it is further preferred to use a phosphate that does not have a linear or branched alkyl group substituted by some substituent on the main chain or the side chain of the alkyl group. In one or more embodiments, examples of the surfactant include hexyl phosphate, heptyl phosphate, octyl phosphate, 2-ethyl hexyl phosphate, decyl phosphate, dodecyl phosphate/lauryl phosphate, myristyl phosphate, and stearyl phosphate. Of these, from the viewpoint of increasing the polishing removal rate of the silicon-containing material and increasing the selectivity of the silicon-containing material with respect to other materials (such as a nitride material), dodecyl phosphate is preferred. The reason thereof is presumed that dodecyl phosphate has a low property of being adsorbed on the silicon-containing material, and is likely to be adsorbed on other materials (such as a nitride material).

The content (concentration) of the surfactant is not particularly limited, and the concentration of the surfactant is preferably 0.1 to 1.0 g/L, more preferably 0.15 to 0.8 g/L, and further preferably 0.2 to 0.5 g/L. According to an embodiment, the concentration of the surfactant is 0.2 to 0.4 g/L or 0.2 to 0.3 g/L. If the polishing composition contains the surfactant with a content within the above range, the removal percentage of a silicon-containing material is increased, and the selectivity of the silicon-containing material with respect to a material other than the silicon material (such as a metal nitride) is increased.

### <pH Adjusting Agent>

In one or more embodiments, the polishing composition may further contain a pH adjusting agent. The value of the pH of the polishing composition can be adjusted by addition of the pH adjusting agent, whereby the chemical polishing effect of the polishing composition or the dispersion stability of the polishing composition can be increased. In an embodiment, the pH adjusting agent used for the present polishing composition may be, for example, an acid. As the acid, it is preferred that inorganic acid is not used, and it is more preferred that organic acid is used. In another embodiment, the pH adjusting agent used in the present polishing composition is more preferably a carboxylic acid (other than amino acid) or an amino acid. If the pH adjusting agent is a carboxylic acid (other than amino acid) or an amino acid, the selectivity of the silicon-containing material with respect to other materials (such as a nitride material) is increased.

In one or more embodiments, where the pH adjusting agent used in the polishing composition is a carboxylic acid, examples of the carboxylic acid include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-pentanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid. In an embodiment, the carboxylic acid may be, for example, a carboxylic acid having carbon atoms of an even number, and is preferably a dicarboxylic acid. In another embodiment, the carboxylic acid may be succinic acid, adipic acid, tartaric acid, or a combination thereof, and is preferably tartaric acid.

In one or more embodiments, where the pH adjusting agent used in the polishing composition is an amino acid, examples of the amino acid include glutamic acid, aspartic acid, or an acidic amino acid of a combination thereof, and the amino acid is preferably aspartic acid.

The addition amount (concentration) of the pH adjusting agent may be appropriately selected so that the polishing composition has a desired pH value, and the amount is preferably an amount that can adjust the pH value of the polishing composition to a preferred pH value described later.

The pH value of the polishing composition of the present embodiment is preferably 2 or more, more preferably 2.5 or more, and further preferably 3 or more. The pH value of the polishing composition of the present embodiment is more preferably less than 6, further preferably 5.5 or less, and particularly preferably 5 or less. The pH value of the polishing composition of the present embodiment is preferably within the range of 3 to 5, and further preferably within the range of 3 to 4. If the pH is within the above range, the removal percentage of a silicon-containing material (such as silicon oxide) of the polishing composition of the present embodiment is increased, and the selectivity of the silicon-containing material with respect to other materials (such as a metal nitride which is TiN) is increased, thereby increasing the stability.

The pH of the polishing composition can be measured by using a pH meter. The pH meter is subjected to three-point calibration by using a standard buffer solution, and then the glass electrode is placed in the polishing composition for 2 minutes or more to allow the pH value to become stable. Then, the pH of the polishing composition can be accurately grasped by measuring the pH value after the value becomes stable.

### <Aqueous Dispersing Medium>

The function of the aqueous dispersing medium in the polishing composition is to dissolve or disperse the respective components as described above in the polishing composition. Examples of the aqueous dispersing medium are not particularly limited. The content of water in the aqueous dispersing medium is not particularly limited, and is preferably 50% by weight or more, and more preferably 90% by weight or more based on the total weight of the aqueous dispersing medium, and the aqueous dispersing medium is further preferably composed of water alone. From the viewpoint of suppressing contamination of the object to be polished and inhibition of the function of other components, the dispersing medium is preferably water containing as few impurities as possible. As such water, water in which the total content of transition metal ions is 100 ppb or less is preferred. The purity of the water can be increased by, for example, operations such as removing impurity ions by using an ion exchange resin, removing foreign matter with a filter, or distillation. Specifically, as the water, it is preferred to use deionized water (ion exchange water), pure water, ultrapure water, distilled water, or the like. In an embodiment, the aqueous dispersing medium contains deionized water.

The aqueous dispersing medium may be a mixed solvent of water and an organic solvent as long as the effect of the present disclosure is not significantly inhibited. The organic solvent is not particularly limited, and a known organic solvent can be used. Where a mixed solvent of water and an organic solvent is used, the organic solvent is preferably mixed with water. Where an organic solvent is used, water and the organic solvent may be mixed together to prepare a mixed solvent and then respective components may be added thereto to be mixed. Alternatively, respective components may be dispersed or dissolved in the organic solvent and be then mixed with water. As the organic solvent, one type thereof may be used alone, or two or more types thereof may be used in combination.

### <Other Components>

The polishing composition of the present embodiment may further contain other components to an extent that the effect of the present disclosure is not inhibited. Other components are not particularly limited, but may be appropriately selected from known various components that are used for the polishing composition such as a wetting agent, a chelating agent, an antiseptic agent, an antifungal agent, dissolved gas, and a reducing agent.

### <Form of Polishing Composition>

The polishing composition of the present embodiment may be a one-pack type or a multi-pack type such as a two-pack type. The multi-pack type is a combination of liquids formed by mixing part of or all of the polishing composition at an arbitrary mixing ratio. The polishing composition may be in the form of a condensed stock solution. In this case, the condensed stock solution can be usable for polishing processing by diluting the condensed stock solution to, for example, 2 to 10 times or more by using a diluting liquid such as water.

### <Method for Producing Polishing Composition>

The method for producing the polishing composition of the present embodiment is not particularly limited, and the polishing composition can be produced by stirring and mixing the abrasive grains, the surfactant, and, as necessary, other components (such as the pH adjusting agent) together in the aqueous dispersing medium (such as water). Details of each component are as described above. The temperature at the time of mixing respective components is not particularly limited as long as the respective components in the polishing composition can be homogeneously mixed.

### <Polishing Method>

Another aspect of the present disclosure provides a polishing method of polishing an object to be polished by using the polishing composition. The polishing method using the polishing composition of the present embodiment is not particularly limited, but is preferably chemical mechanical polishing. The polishing process may be a polishing process composed of a single step, or a polishing process composed of a plurality of steps. The polishing process composed of a plurality of steps may be, for example, a process in which a preliminary polishing step (rough polishing step) is performed and then a final polishing step is performed, or a process in which a first polishing step is performed, and then a second polishing step is performed once or more, followed by performing a final polishing step.

### <Polishing Apparatus>

In one or more embodiments, the polishing apparatus that uses the polishing composition of the present embodiment is not particularly limited, and, for example, may be an apparatus that can subject the object to be processed to flattening processing, selecting processing, and cleaning processing. The surface treatment apparatus (polishing apparatus) may be a common polishing apparatus having a holder for holding a substrate or the like having the object to be polished, a motor in which the rotation speed can be changed, and the like provided therein, and having a polishing table to which a polishing pad (polishing cloth) can be sticked.

Common nonwoven fabric, polyurethane, porous fluororesin, and the like can be used as the polishing pad without particular limitation. It is preferred that the polishing pad has been subjected to grooving so that polishing liquid is stored.

In an embodiment, the polishing conditions used in the polishing method are not particularly limited, and appropriate conditions can be appropriately set in accordance with the properties of the polishing composition and the object to be polished. For example, the rotation speeds of the polishing table and the carrier are not particularly limited, but are preferably 10 rpm or more and 500 rpm or less, more preferably 20 rpm or more and 300 rpm or less, further preferably 30 rpm or more and 200 rpm or less, and further preferably 40 rpm or more and 150 rpm or less. The pressure applied to the substrate having the object to be polished (polishing pressure) is not particularly limited, but, generally the pressure is preferably 0.1 psi or more and 10 psi or less, more preferably 0.5 psi or more and 8 psi or less, and further preferably 1 psi or more and 5 psi or less per unit area. If the rotation speeds and the pressure are within these ranges, occurrence of damage of the substrate and occurrence of defects such as damage on the surface due to the load can be further suppressed, while obtaining high polishing removal rate. The method for supplying the polishing composition is not particularly limited, and a method in which the polishing composition is continuously supplied with a pump or the like (continuous supply) may be adopted. Generally, the supply amount of the polishing composition is preferably such that the surface of the polishing pad is covered with the polishing composition of the present embodiment, but is not particularly limited. After finishing polishing, for example, the substrate is cleaned in running water, and then water droplets adhered to the substrate are blown off to dry the substrate by using a spin dryer or the like, whereby a substrate having a processed surface can be obtained.

### <Selectivity>

The polishing composition of the present embodiment has a high selectivity of the silicon-containing material with respect to other materials (such as a nitride material). In an embodiment, when an object to be polished is polished by using the polishing composition of the present embodiment, and the polishing removal rate (A/min) of the TEOS (silicon oxide film) is divided by the polishing removal rate of the TiN (titanium nitride film) to calculate a selectivity, in the present embodiment, the value of the selectivity (TEOS/TiN) is preferably 100 or more, and, further, is more preferably 200 or more, 400 or more, 600 or more, 800 or more, 1000 or more, 1500 or more, 2000 or more, or 2500 or more. According to an embodiment, the polishing composition of the present embodiment can polish an object to be polished (the silicon oxide film and the titanium nitride film) so that the selectivity (TEOS/TiN) between the polishing removal rate of the silicon oxide film (TEOS) and the polishing removal rate of the titanium nitride film (TiN) is 200 or more. The value of the selectivity is determined based on each polishing removal rate measured by the method described in Examples.

Embodiments of the present disclosure are described above in detail, but the description is merely illustrative and exemplary, and it is not intended to limit the disclosure thereby. It needs to be understood that the scope of the present disclosure has to be interpreted based on the attached claims.

The present disclosure encompasses the following aspects and embodiments.

1. A polishing composition comprising: abrasive grains having surfaces modified with a silane coupling agent and having a positive surface potential, and having an average secondary particle size of 45 nm or more and 100 nm or less, and a silanol group density of more than 0.0/nm² and 3.0/nm² or less; a surfactant which is an alkyl phosphate having 6 to 18 carbon atoms; and an aqueous dispersing medium.

2. The polishing composition according to the “1.”, further comprising a pH adjusting agent.

3. The polishing composition according to the “2.”, wherein the pH adjusting agent is a carboxylic acid (other than amino acid), or an amino acid.

4. The polishing composition according to the “3.”, wherein a number of carbon atoms of the carboxylic acid is an even number.

5. The polishing composition according to the “3.” or “4.”, wherein the carboxylic acid is a dicarboxylic acid.

6. The polishing composition according to the “3.”, wherein the carboxylic acid is at least one selected from the group consisting of succinic acid, adipic acid, and tartaric acid.

7. The polishing composition according to the “3.”, wherein the carboxylic acid is tartaric acid.

8. The polishing composition according to the “3.”, wherein the amino acid is an acidic amino acid.

9. The polishing composition according to the “3.”, wherein the amino acid is at least one selected from the group consisting of glutamic acid and aspartic acid.

10. The polishing composition according to the “3.”, wherein the amino acid is aspartic acid.

11. The polishing composition according to any of the “1.” to the “10.”, wherein a pH value of the polishing composition is within a range of 3 to 5.

12. The polishing composition according to any of the “1.” to the “11.”, wherein the surfactant is an alkyl phosphate having 8 to 15 carbon atoms.

13. The polishing composition according to any of the “1.” to the “12.”, wherein the surfactant is an alkyl phosphate having 10 to 14 carbon atoms.

14. The polishing composition according to any of the “1.” to the “13.”, wherein a concentration of the surfactant is 0.1 to 1.0 g/L.

15. The polishing composition according to any of the “1.” to the “14.”, wherein the abrasive grains are modified with a silane coupling agent having an amino group.

16. The polishing composition according to the “15.”, wherein the silane coupling agent is (3-aminopropyl)triethoxysilane (APTES).

17. The polishing composition according to any of the “1.” to the “16.”, wherein a selectivity (TEOS/TiN) between a polishing removal rate of a silicon oxide film (TEOS) and a polishing removal rate of a titanium nitride film (TiN) is 200 or more.

18. A polishing method comprising the steps of: providing a polishing apparatus comprising a polishing pad and a polishing head; setting an object to be polished between the polishing pad and the polishing head; and polishing the object to be polished by using the polishing composition according to any one of the “1.” to the “17.”.

19. The polishing method according to the “18.”, wherein the object to be polished is a substrate comprising a first surface facing the polishing head and being an outermost surface, and a second surface located under the first surface, and wherein the object in which at least a metal nitride is present on the second surface of the substrate is polished.

20. The polishing method according to the “19.”, wherein the metal nitride comprises titanium nitride (TiN).

21. A method for producing a semiconductor substrate comprising the polishing method according to any of the “18.” to the “20.”.

### EXAMPLES

The present disclosure will hereinafter be described in more detail with reference to Examples and Comparative Examples. However, the technical scope of the present disclosure is not limited to the Examples below. Unless otherwise specified, the term “%” refers to “% by weight (wt %)”. In Examples described later, unless otherwise specified, all of the polishing operations were performed under the condition of room temperature (20 to 25° C.) and a relative humidity of 40 to 50% RH.

### <Preparation of Polishing Composition>

### Example 1

0.3 g of (3-aminopropyl)triethoxysilane (APTES) as an additive 1 was added to ultrapure water to dilute it, which was then added to 1 kg of 20% by weight colloidal silica while being stirred. The stirring speed was set to 230 rpm, and the adding speed of the diluting liquid was set to 10 ml/min. After the addition, stirring was continued at 230 rpm for 4 hours to allow the (3-aminopropyl)triethoxysilane to be bonded to the surface of the colloidal silica (coupling).

The colloidal silica having the additive 1 adsorbed thereon was weighed out by 130 g. Then, 400 g of ultrapure water was added thereto, and 0.15 g of dodecyl phosphate as an additive 2 was added thereto. Next, an arbitrary amount of tartaric acid as a pH adjusting agent and ultrapure water were added thereto to adjust the weight and the concentration so that the final weight was 1000 g and the final concentration of the colloidal silica in the polishing composition was 2% by weight.

### Examples 2 to 14 and Comparative Examples 1 to 9

The polishing compositions of Examples 2 to 14 and Comparative Examples 1 to 5 were each prepared by mixing abrasive grains, and an additive 2 together in a dispersing medium (ultrapure water) in accordance with the preparation method in Example 1 and with reference to the concentration described in Tables 1 to 5, and then adjusting the pH value to the numerical value shown in Tables 1 to 5 with a pH adjusting agent. In Comparative Example 6, the polishing composition was prepared by the same preparation method as in Example 1 except that an additive 1 was not used. In Comparative Example 7, the polishing composition was prepared by the same preparation method as in Example 1 except that the method for surface-treating the colloidal silica was different. Specifically, in Comparative Example 7, a silane coupling agent of 3-mercaptopropyltrimethoxysilane was bonded to colloidal silica (coupling) and then the sulfhydryl was oxidized with hydrogen peroxide to obtain colloidal silica having a sulfonic acid bonded to the surface thereof. In Comparative Examples 8, by using tetraethylammonium hydroxide (TEAH) as an additive 1, processing was performed in the same manner as with APTES of Example 1, and then the polishing composition was prepared by the same preparation method as in Example 1. In Comparative Examples 9, by using cetyltrimethylammonium bromide as an additive 1, processing was performed in the same manner as with APTES of Example 1, and then the polishing composition was prepared by the same preparation method as in Example 1.

### <Measurement of pH Value>

The pH of the polishing composition can be checked by using a pH meter (manufactured by HORIBA, Ltd.; LAQUA F-73). The pH value of the polishing composition was measured at a measurement temperature of 25° C. The average secondary particle size of the colloidal silica in each of these Examples was measured by a laser light scattering measurement apparatus (manufactured by Malvern Panalytical Ltd; Zetasizer Ultra)

The mark “-” in Tables 1 to 5 below indicates that the component is not added. The compounds used for preparing the polishing compositions described in Tables 1 to 5 and the properties thereof are shown below.
(3-aminopropyl)triethoxysilane (APTES)
3-mercaptopropyltrimethoxysilane
Tetraethylammonium hydroxide (TEAH)
Cetyltrimethylammonium bromide
Hexyl phosphate
Octyl phosphate
2-ethyl hexyl phosphate
Dodecyl phosphate
Hexadecyl phosphate
Eicosyl phosphate
Tartaric acid
L-aspartic acid (hereinafter described as “aspartic acid”)

TABLE 1

| | Colloidal silica | | | | | | | | | | |
|---|---|---|---|---|---|---|---|---|---|---|---|
| | Average | Physical | | | | | | | | | |
| | secondary | property 1 | Additive 1 | | | Additive 2 | | | pH adjusting agent | | Physical |
| | particle | Silanol | | | Concen- | | | Concen- | | Concen- | property |
| | size | group | Name of | Molecular | tration | | Molecular | tration | | tration | pH |
| | nm | [/nm²] | compound | weight | [g/L] | Surfactant | weight | [g/L] | Component | [g/L] | [—] |
| Comparative | 63 | 1.6 | APTES | 221 | 0.03 | — | — | — | Tartaric acid | 0.15 | 3.5 |
| Example 1 | | | | | | | | | | | |
| Example 1 | 63 | 1.6 | APTES | 221 | 0.03 | Dodecyl | 266 | 0.15 | Tartaric acid | 0.5 | 3.5 |
| | | | | | | phosphate | | | | | |
| Example 2 | 63 | 1.6 | APTES | 221 | 0.03 | Dodecyl | 266 | 0.20 | Tartaric acid | 0.5 | 3.3 |
| | | | | | | phosphate | | | | | |
| Example 3 | 63 | 1.6 | APTES | 221 | 0.03 | Dodecyl | 266 | 0.30 | Tartaric acid | 0.5 | 3.3 |
| | | | | | | phosphate | | | | | |
| Example 4 | 63 | 1.6 | APTES | 221 | 0.03 | Dodecyl | 266 | 0.50 | Tartaric acid | 0.5 | 3.5 |
| | | | | | | phosphate | | | | | |
| Example 5 | 63 | 1.6 | APTES | 221 | 0.03 | Dodecyl | 266 | 0.10 | Aspartic acid | 0.5 | 3.5 |
| | | | | | | phosphate | | | | | |
| Example 6 | 63 | 1.6 | APTES | 221 | 0.03 | Dodecyl | 266 | 0.15 | Aspartic acid | 0.5 | 3.4 |
| | | | | | | phosphate | | | | | |
| Example 7 | 63 | 1.6 | APTES | 221 | 0.03 | Dodecyl | 266 | 0.20 | Aspartic acid | 0.5 | 3.5 |
| | | | | | | phosphate | | | | | |
| Example 8 | 63 | 1.6 | APTES | 221 | 0.03 | Dodecyl | 266 | 0.30 | Aspartic acid | 0.5 | 3.5 |
| | | | | | | phosphate | | | | | |
| Example 9 | 63 | 1.6 | APTES | 221 | 0.03 | Dodecyl | 266 | 0.50 | Aspartic acid | 0.5 | 3.5 |
| | | | | | | phosphate | | | | | |

TABLE 2

| | Colloidal silica | | | | | | | | | | |
|---|---|---|---|---|---|---|---|---|---|---|---|
| | Average | Physical | | | | | | | | | |
| | secondary | property 1 | Additive 1 | | | Additive 2 | | | pH adjusting agent | | Physical |
| | particle | Silanol | | | Concen- | | | Concen- | | Concen- | property |
| | size | group | Name of | Molecular | tration | | Molecular | tration | | tration | pH |
| | nm | [/nm²] | compound | weight | [g/L] | Surfactant | weight | [g/L] | Component | [g/L] | [—] |
| Example 4 | 63 | 1.6 | APTES | 221 | 0.03 | Dodecyl | 266 | 0.50 | Tartaric acid | 0.5 | 3.5 |
| | | | | | | phosphate | | | | | |
| Example 10 | 63 | 1.6 | APTES | 221 | 0.03 | 2-ethylhexyl | 210 | 0.50 | Tartaric acid | 0.5 | 3.3 |
| | | | | | | phosphate | | | | | |
| Example 11 | 63 | 1.6 | APTES | 221 | 0.03 | 2-ethylhexyl | 210 | 1.00 | Tartaric acid | 0.5 | 3.3 |
| | | | | | | phosphate | | | | | |
| Comparative | 63 | 1.6 | APTES | 221 | 0.03 | Ammonium | 283 | 0.50 | Tartaric acid | 0.5 | 3.5 |
| Example 2 | | | | | | dodecyl sulfate | | | | | |

TABLE 3

| | Colloidal silica | | | | | | | | | | |
|---|---|---|---|---|---|---|---|---|---|---|---|
| | Average | Physical | | | | | | | | | |
| | secondary | property 1 | Additive 1 | | | Additive 2 | | | pH adjusting agent | | Physical |
| | particle | Silanol | | | Concen- | | | Concen- | | Concen- | property |
| | size | group | Name of | Molecular | tration | | Molecular | tration | | tration | pH |
| | nm | [/nm²] | compound | weight | [g/L] | Surfactant | weight | [g/L] | Component | [g/L] | [—] |
| Example 7 | 63 | 1.6 | APTES | 221 | 0.03 | Dodecyl | 266 | 0.20 | Aspartic acid | 0.5 | 3.5 |
| | | | | | | phosphate | | | | | |
| Example 12 | 63 | 1.6 | APTES | 221 | 0.03 | Hexyl | 182 | 0.20 | Aspartic acid | 0.5 | 3.5 |
| | | | | | | phosphate | | | | | |
| Example 13 | 63 | 1.6 | APTES | 221 | 0.03 | Octyl | 210 | 0.20 | Aspartic acid | 0.5 | 3.5 |
| | | | | | | phosphate | | | | | |
| Example 14 | 63 | 1.6 | APTES | 221 | 0.03 | Hexadecyl | 322 | 0.20 | Aspartic acid | 0.5 | 3.5 |
| | | | | | | phosphate | | | | | |
| Comparative | 63 | 1.6 | APTES | 221 | 0.03 | Eicosyl | 378 | 0.20 | Aspartic acid | 0.5 | 3.5 |
| Example 3 | | | | | | phosphate | | | | | |

TABLE 4

| | Colloidal silica | | | | | | | | | | |
|---|---|---|---|---|---|---|---|---|---|---|---|
| | Average | Physical | | | | | | | | | |
| | secondary | property 1 | Additive 1 | | | Additive 2 | | | pH adjusting agent | | Physical |
| | particle | Silanol | | | Concen- | | | Concen- | | Concen- | property |
| | size | group | Name of | Molecular | tration | | Molecular | tration | | tration | pH |
| | nm | [/nm²] | compound | weight | [g/L] | Surfactant | weight | [g/L] | Component | [g/L] | [—] |
| Example 2 | 63 | 1.6 | APTES | 221 | 0.03 | Dodecyl | 266 | 0.20 | Tartaric acid | 0.5 | 3.3 |
| | | | | | | phosphate | | | | | |
| Comparative | 44 | 1.6 | APTES | 221 | 0.03 | Dodecyl | 266 | 0.20 | Tartaric acid | 0.5 | 3.5 |
| Example 4 | | | | | | phosphate | | | | | |
| Comparative | 65 | 3.1 | APTES | 221 | 0.03 | Dodecyl | 266 | 0.20 | Tartaric acid | 0.5 | 3.5 |
| Example 5 | | | | | | phosphate | | | | | |

TABLE 5

| | Colloidal silica | | | | | | | | | | |
|---|---|---|---|---|---|---|---|---|---|---|---|
| | Average | Physical | | | | | | | | | |
| | secondary | property 1 | Additive 1 | | | Additive 2 | | | pH adjusting agent | | Physical |
| | particle | Silanol | | | Concen- | | | Concen- | | Concen- | property |
| | size | group | | Molecular | tration | | Molecular | tration | | tration | pH |
| | nm | [/nm²] | Name of compound | weight | [g/L] | Surfactant | weight | [g/L] | Component | [g/L] | [—] |
| Comparative | 63 | 1.6 | None | | | Dodecyl | 266 | 0.20 | Aspartic acid | 0.5 | 3.5 |
| Example 6 | | | | | | phosphate | | | | | |
| Comparative | 63 | 1.6 | 3-mercaptopropyl- | 238 | 0.03 | Dodecyl | 266 | 0.20 | Aspartic acid | 0.5 | 3.5 |
| Example 7 | | | trimethoxysilane* | | | phosphate | | | | | |
| Comparative | 63 | 1.6 | TEAH | 91 | 0.03 | Dodecyl | 266 | 0.20 | Tartaric acid | 0.5 | 3.5 |
| Example 8 | | | | | | phosphate | | | | | |
| Comparative | 63 | 1.6 | Cetyltrimethyl- | 365 | 0.05 | Dodecyl | 266 | 0.20 | Tartaric acid | 0.5 | 3.5 |
| Example 9 | | | ammonium bromide | | | phosphate | | | | | |

*Colloidal silica having a sulfonic acid immobilized on the surface thereof, the sulfonic acid being obtained by mixing 3-mercaptopropyltrimethoxysilane in a colloidal silica solution to bond the 3-mercaptopropyltrimethoxysilane to colloidal silica (coupling) and then oxidizing the thiol group with hydrogen peroxide

### <Evaluation of Polishing Performance>

### (Provision of Object to be Polished)

As the object to be polished, a wafer having a tetraethyl orthosilicate (TEOS) film having a thickness of 12000 Å laminated thereon by a plasma enhanced chemical vapor disposition (PECVD) method, or a wafer having a titanium nitride film having a thickness of 3600 Å laminated thereon by a physical vapor deposition (PVD) method was provided.

### (Polishing Conditions)

By using the polishing composition obtained by the preparation of the polishing composition as described above, each of the wafers was polished under the following conditions.

Polishing apparatus: CMP polishing apparatus (manufactured by EBARA CORPORATION: product name: FREX 300SII)

Polishing pad: polyurethane pad (manufactured by Dow Electronic Materials; product name: IC1010)

Dresser: diamond dresser (manufactured by 3M Company; product name: A188)

Polishing time for TEOS film: 60 seconds

Polishing time for TiN film: 60 seconds

Pressure of polishing table: 140 hPa (2.03 psi)

Rotation speed of polishing table: 90 rpm

Rotation speed of carrier: 91 rpm

Supply rate of polishing composition: 200 ml/minute

### (Dressing Conditions)

By using pure water, the polishing pad was subjected to dressing under the following conditions. The polishing apparatus, the polishing pad, and the dresser used are the same as the ones described in the polishing conditions above.

Rotation speed of polishing table during dressing: 90 rpm

Pressure applied to polishing table (polishing pad) of dresser: 22 N

Dressing time: In-situ

Flow rate of pure water flowed during dressing: 2,000 ml/minute

### (Calculation of Polishing Removal Rate)

With regard to the condition of the TEOS film, the film thicknesses before and after polishing were measured by using a spectral ellipsometry film thickness measurement apparatus (manufactured by KLA-Tencor; product name: ASET F5x), and the polishing removal rate of the TEOS film was calculated based on the difference in the thickness.

With regard to the condition of the TiN film, the film thicknesses before and after polishing were measured by using a sheet resistance-based film thickness measurement apparatus (manufactured by KLA-Tencor; product name: OmniMap RS-100), and the polishing removal rate of the TiN film was calculated based on the difference in the thickness.

### (Measurement of Stability)

By using a disk centrifugal particle size distribution measurement apparatus (manufactured by CPS Instruments, Inc.; product name: DC24000UHR), the median diameter (D50) of the silica was measured right after preparation of the polishing composition of each of the Examples 1 to 14 and Comparative Examples 1 to 9 and after the polishing composition was stored for two weeks at 80° C. If the change in the median diameter (D50) of the silica was 5% or less, the stability of the polishing composition was determined to be satisfactory (marked with a circle), and if the change in the median diameter (D50) of the silica was more than 5%, the stability of the polishing composition was determined to be unsatisfactory (marked with a cross mark).

The evaluation results of the polishing compositions of the Examples and Comparative Examples are shown in Table 6 below. In the column of “Selectivity” in Table 6, in the column of “TEOS/TiN”, the value obtained by dividing the polishing removal rate of silica by the polishing removal rate of TEOS is shown.

TABLE 6

| | Polishing removal rate | | | |
|---|---|---|---|---|
| | TEOS | TiN | Selectivity | |
| | [Å/min] | [Å/min] | TEOS/TiN | Stability |
| Example 1 | 1961 | 6.0 | 327 | ∘ |
| Example 2 | 1921 | 3.0 | 649 | ∘ |
| Example 3 | 1921 | 1.4 | 1412 | ∘ |
| Example 4 | 1814 | 2.4 | 756 | ∘ |
| Example 5 | 1839 | 4.4 | 418 | ∘ |
| Example 6 | 1961 | 2.7 | 721 | ∘ |
| Example 7 | 1920 | 0.7 | 2666 | ∘ |
| Example 8 | 1900 | 0.6 | 3393 | ∘ |
| Example 9 | 1860 | 1.0 | 1938 | ∘ |
| Example 10 | 1691 | 13.0 | 130 | ∘ |
| Example 11 | 1116 | 1.6 | 698 | ∘ |
| Example 12 | 1770 | 12.0 | 148 | ∘ |
| Example 13 | 1785 | 3.4 | 519 | ∘ |
| Example 14 | 1787 | 1.7 | 1063 | ∘ |
| Comparative Example 1 | 1845 | 123.7 | 15 | ∘ |
| Comparative Example 2 | 1404 | 94.9 | 15 | ∘ |
| Comparative Example 3 | Deposition | Deposition | — | x |
| Comparative Example 4 | 377 | 147.4 | 3 | ∘ |
| Comparative Example 5 | 116 | 46.0 | 3 | ∘ |
| Comparative Example 6 | 1374 | 1.8 | 781 | x |
| Comparative Example 7 | 32 | 4.0 | 8 | ∘ |
| Comparative Example 8 | 1391 | 1.8 | 790 | x |
| Comparative Example 9 | 23 | 3.2 | 7 | x |

As shown by the results in Table 6 above, the polishing compositions of Examples 1 to 14 are more excellent in the stability than the polishing compositions of Comparative Examples 3, 6, 8, and 9. The polishing compositions of Examples 1 to 14 each had a removal percentage of the silicon of 1000 Å/min or more and a removal percentage of the titanium nitride of 20 Å/min or less. As is clear from this fact, the selectivity of the silica with respect to titanium nitride of the polishing composition of the present disclosure is high (the selectivity is more than 100 in all Examples), and, in particular, the polishing compositions of Examples 2 to 4, 6 to 9, 11, 13, and 14 each have a selectivity of 500 or more.

### INDUSTRIAL APPLICABILITY

The present disclosure provides a polishing composition having a high removal percentage of silicon and a high selectivity of the silicon material with respect to other materials (such as a nitride film), and being excellent in the stability.

The features of the embodiments described above are useful for a person having ordinary skill in the art to understand the present disclosure. A person having ordinary skill in the art should understand that the object and/or advantages same as those of the embodiments can be achieved by designing another process and structure and making changes based on the present disclosure. A person having ordinary skill in the art should also understand that such equivalent substitution does not deviate from the spirit or the scope of the present disclosure, and that modification, substitution, or change could be made as long as such modification, substitution, or change does not deviate from the spirit or the scope of the present disclosure.

The present application is based on the Japanese patent application No. 2024-166347, which is a foreign language written application filed on Sep. 25, 2024, and the disclosed content thereof is incorporated herein as a whole by reference.

1. A polishing composition comprising:
abrasive grains having surfaces modified with a silane coupling agent and having a positive surface potential, and having an average secondary particle size of 45 nm or more and 100 nm or less, and a silanol group density of more than 0.0/nm2 and 3.0/nm2 or less;
a surfactant which is an alkyl phosphate having 6 to 18 carbon atoms; and
an aqueous dispersing medium.

2. The polishing composition according to claim 1, further comprising a pH adjusting agent.

3. The polishing composition according to claim 2, wherein the pH adjusting agent is a carboxylic acid (other than amino acid), or an amino acid.

4. The polishing composition according to claim 3, wherein a number of carbon atoms of the carboxylic acid is an even number.

5. The polishing composition according to claim 3, wherein the amino acid is an acidic amino acid.

6. The polishing composition according to claim 1, wherein a pH value of the polishing composition is within a range of 3 to 5.

7. The polishing composition according to claim 1, wherein a concentration of the surfactant is 0.1 to 1.0 g/L.

8. The polishing composition according to claim 1, wherein the abrasive grains are modified with a silane coupling agent having an amino group.

9. The polishing composition according to claim 8, wherein the silane coupling agent is (3-aminopropyl)triethoxysilane (APTES).

10. A polishing method comprising the steps of:
providing a polishing apparatus comprising a polishing pad and a polishing head;
setting an object to be polished between the polishing pad and the polishing head; and
polishing the object to be polished by using the polishing composition according to claim 1.

11. The polishing method according to claim 10,
wherein the object to be polished is a substrate comprising a first surface facing the polishing head and being an outermost surface, and a second surface located under the first surface, and
wherein the object in which at least a metal nitride is present on the second surface of the substrate is polished.

12. The polishing method according to claim 11, wherein the metal nitride comprises titanium nitride (TiN).

13. A method for producing a semiconductor substrate comprising the polishing method according to claim 10.
